(19) United States
(12) Patent Application Publication
(10) Pub. No.: US 2022/0068777 A1
(43) Pub. Date: Mar. 3, 2022

(54) LOW-INDUCTANCE CONNECTING DEVICE FOR CONNECTING A SEMICONDUCTOR MODULE AND AN INTERMEDIATE CIRCUIT CAPACITOR

(71) Applicant: Robert Bosch GmbH, Stuttgart (DE)

(72) Inventors: Christine Arenz, Stuttgart (DE); Gunter Flamm, Sonnenbuehl (DE); Michael Maercker, Stuttgart (DE); Reiner Schuetz, Ditzingen (DE)

(21) Appl. No.: 17/415,032

(22) PCT Filed: Nov. 25, 2019
(86) PCT No.: PCT/EP2019/082337

§ 371 Date: Jun. 17, 2021

(30) Foreign Application Priority Data
Dec. 18, 2018 (DE) 10 2018 222 017.4
Mar. 1, 2019 (DE) 10 2019 202 777.6

(51) Int. Cl. H01L 23/498; H01G 4/228; H05K 1/02; H01L 23/64; H02M 7/00

(52) U.S. Cl. CPC H01L 23/49811; H01G 4/228; H02M 7/003; H01L 23/642; H05K 1/0231

(57) ABSTRACT

Low-inductance connecting device (10) for connecting a semiconductor module (20) to an intermediate circuit capacitor (30), comprising at least one first contact region (11a) and one second contact region (12) which has opposite polarity to the first contact region (11a), which first and second contact region are designed to make contact with the semiconductor module (20), at least one third contact region (13a) which has the same polarity as the first contact region (11a) and one fourth contact region (14) which has opposite polarity to the third contact region (13a), which third and fourth contact regions are designed to make contact with the intermediate circuit capacitor (30), at least one first connecting region (15a) which is designed to connect the first contact region (11a) and the third contact region (13a) to one another, and at least one second connecting region (16a) which is designed to connect the second contact region (12) and the fourth contact region (14) to one another, wherein the first connecting region (15a) and the second connecting region (16a) are each designed as planar busbars which are separate from one another.

### BACKGROUND OF THE INVENTION

The present invention relates to a low-inductance connecting device, in particular between a semiconductor module and an intermediate circuit capacitor.

Connections between a semiconductor module and an intermediate circuit capacitor are usually designed in such a way that they have particularly small negative effects on the circuit. The overall inductance of the circuit is often a key factor. The effective total inductance, or intermediate circuit inductance, is the sum of the inductances of the semiconductor module, the intermediate circuit capacitor, and the connection between the two components.

It is critically important to minimize the inductance of the commutation cell, in particular when fast switching components such as inverters and converters are used. Switching of the component leads to a time- and inductance-dependent current peak, wherein the faster the component switches and the higher the total inductance, the greater the size of the current peak. In order to avoid damage to the components due to excessive voltage peaks, the maximum switching speed of the component that can be designed is limited by the total inductance of the circuit.

Usually, the connection of such components is implemented by means of wire bonds, in particular thick wire bonds. Especially when modern, rapidly switching SiC components are used, the connection inductance of such connections is too high. For this reason, for example, semiconductor modules and an intermediate circuit capacitor are connected to each other with as low inductance as possible.

In previous connection designs, a connection of the components is therefore implemented by means of ribbon bonds in order to further reduce the connection inductance.

### SUMMARY OF THE INVENTION

For the reasons stated above, there is a desire to further reduce the connection inductance.

A proposed low-inductance connecting device, for connecting a semiconductor module to an intermediate circuit capacitor, comprises at least one first contact region and a second contact region which has opposite polarity to the first contact region, both contact regions being designed to contact the semiconductor module, at least one third contact region which has the same polarity as the first contact region, and a fourth contact region which has opposite polarity to the third contact region, both contact regions being designed to contact the intermediate circuit capacitor, at least one first connecting region which is designed to connect the first contact region and the third contact region to one another, and at least one second connecting region which is designed to connect the second contact region and the fourth contact region to one another. The first connecting region and the second connecting region are each designed as planar busbars which are separate from each other.

In this way, the electrical currents through the negative path of the connecting device travel at least partly in the opposite direction to the electrical currents through the positive path of the connecting device. Thus, the magnetic fields which are induced by the current flow through the respective opposite-polarity paths of the connecting device at least partially compensate each other. This further reduces the connection inductance and thus the intermediate circuit inductance.

In this way, it is possible to establish a connection between the semiconductor module and the intermediate circuit capacitor, in which the respective connection lengths of the opposite-polarity paths are the same length. This can prevent different-sized loops of the opposite-polarity paths of the connecting device. This means that the connection inductance and hence the intermediate circuit inductance can be further reduced.

Preferably, the first connecting region and the second connecting region are designed as sheet metal strips.

Preferably, the first connecting region and the second connecting region are formed by deep drawing or as stamped-bent parts, but can be produced by any other method considered suitable by the person skilled in the art.

In a preferred design, the first connecting region and the second connecting region are preferably arranged plane-parallel to each other.

This makes it particularly simple to achieve the above-described cancellation of current-induced magnetic fields. This further reduces the connection inductance and hence the intermediate circuit inductance.

In a preferred design, the first contact region, the second contact region, the third contact region and the fourth contact region are arranged plane-parallel to one another. The first connecting region and the second connecting region are preferably arranged perpendicular to the contact regions.

In this way, the junction between the first connecting region and the first contact region as well as the third contact region can be provided such that it is separated from the junction between the second connecting region and the second contact region as well as the fourth contact region. This makes it particularly simple to achieve the above-described cancellation of current-induced magnetic fields. This further reduces the connection inductance and hence the intermediate circuit inductance.

Preferably, the first connecting region and the second connecting region are arranged parallel to one another.

Preferably, the first connecting region has a first contact section at which the first connecting region is connected to the first contact region, and a second contact section at which the first connecting region is connected to the third contact region, the first contact section and the second contact section being arranged parallel or plane-parallel to each other.

Preferably, the second connecting region has a third contact section on which the second connecting region is connected to the second contact region, and a fourth contact section on which the second connecting region is connected to the fourth contact region, the third contact section and the fourth contact section being arranged parallel or plane-parallel to each other.

More preferably, the first connecting region and the second connecting region each have angled sections, wherein the angled sections of the first connecting region are arranged parallel to the angled sections of the second connecting region.

Thus, connecting points of the first connecting region and the second connecting region with the first contact region and the third contact region respectively, as well as the second contact region and the fourth contact region, can each be arranged offset perpendicular to the connecting regions without exerting a negative influence on the connection inductance.

In a preferred design, the first connecting region and the second connecting region are separated from each other only by an insulating layer.

Preferably, the insulating layer is formed by an insulating foil or a paper layer, in particular with a thickness of less than 100 microns.

Thus, the distance between the first connecting region and the second connecting region can be minimized. This means that the magnetic fields induced by the current flow through the opposite-polarity paths of the connecting regions are compensated. This further reduces the connection inductance and hence the intermediate circuit inductance.

In a preferred design, the first connecting region and the second connecting region are each designed as laminated planar busbars which are separated from each other.

Due to the planar construction of a busbar, the connecting regions form smaller loops compared to designs with bond ribbons.

This means that the connection inductance and hence the intermediate circuit inductance can be further reduced.

In a preferred design, the distance between the first connecting region and the second connecting region is constant.

This means that the magnetic fields induced by the current flow through the opposite-polarity paths of the connecting regions are compensated. This further reduces the connection inductance and thus the intermediate circuit inductance.

In a preferred design, the second connecting region is at least partially congruent with the first connecting region. Preferably, the second contact region and/or the fourth contact region are formed congruent with the respective first contact region and the third contact region.

The higher the congruence of the first connecting region with the second connecting region, the better the compensation of the magnetic fields induced by the current flow through the respective opposite-polarity paths of the connecting regions. This further reduces the connection inductance and thus the intermediate circuit inductance.

In a preferred design, the intermediate circuit capacitor is designed with an intermediate circuit busbar.

This means that the connection inductance and hence the intermediate circuit inductance can be further reduced.

In a preferred design, the intermediate circuit capacitor is designed with a stepped intermediate circuit busbar with a first step and a second step, wherein the second step is offset parallel to the first step, and a contact region which contacts the first step is extended in such a way that it is guided over the second step in a planar manner and insulated therefrom.

In this way, it is possible to establish a connection between the semiconductor module and the intermediate circuit capacitor for which the respective connection lengths of the opposite-polarity paths are the same length. This can prevent different-sized loops of the opposite-polarity paths of the connecting device. This means that the connection inductance and hence the intermediate circuit inductance can be further reduced.

### BRIEF DESCRIPTION OF THE DRAWINGS

Further measures which improve the invention are described in greater detail below together with the description of the preferred exemplary embodiments of the invention by reference to the figures.

In the drawings:

FIG. 1 shows a connecting device according to a first embodiment;

FIG. 2 shows a connecting device according to a second embodiment;

FIG. 3 shows a connecting device according to a third embodiment; and

FIG. 4 shows a schematic representation of the flow of current through a connecting device according to the third embodiment.

### DETAILED DESCRIPTION

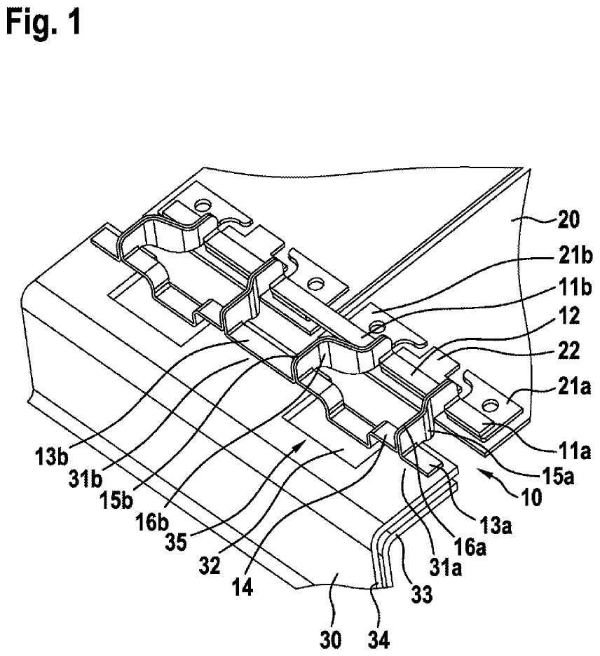

FIG. 1 shows a connecting device 10 according to a first embodiment for connecting a semiconductor module 20 to an intermediate circuit capacitor 30. The connecting device 10 comprises a positive first contact region 11a, a negative second contact region 12, a positive third contact region 13a, and a negative fourth contact region 14.

The semiconductor module 20 comprises a positive first semiconductor contact region 21a and a negative second semiconductor contact region 22. In addition, the semiconductor module 20 has a positive third semiconductor contact region 21b, which is electrically connected to the first semiconductor contact region 21a. The first semiconductor contact region 21a and the third semiconductor contact region 21b surround the second semiconductor contact region 22.

The intermediate circuit capacitor 30 comprises a positive first intermediate circuit contact region 31a and a negative second intermediate circuit contact region 32. In addition, the intermediate circuit capacitor 30 has a positive third intermediate circuit contact region 31b which is electrically connected to the first intermediate circuit contact region 31a. The first intermediate circuit contact region 31a and the third intermediate circuit contact region 31b surround the second intermediate circuit contact region 32.

This particular design, in which a further positive contact region is provided, i.e. the third semiconductor contact region 21b of the semiconductor module 20 and the third intermediate circuit contact region 31b, helps to reduce the connection inductance. In the same way, an additional negative contact region can also be provided.

Therefore, the connecting device 10 additionally comprises a positive fifth contact region 11b and a positive sixth contact region 13b.

The first contact region 11a contacts the first semiconductor contact region 21a. The second contact region 12 contacts the second semiconductor contact region 22. The third contact region 13a contacts the third intermediate circuit contact region 31. The fourth contact region 14 contacts the fourth intermediate circuit contact region 32. The fifth contact region 11b contacts the third semiconductor contact region 21b. The sixth contact region 13b contacts the third intermediate circuit contact region 31b.

The connecting device 10 has a positive first connecting region 15a, which connects the first contact region 11a and the third contact region 13a to each other. In addition, the connecting device 10 has a negative second connecting region 16a which connects the second contact region 12 and the fourth contact region 14 to each other. In addition, the connecting device 10 comprises a negative fourth connecting region 16b which also connects the second contact region 12 and the fourth contact region 14 to each other. In addition, the connecting device 10 comprises a positive third connecting region 15b which connects the fifth contact region 11b and a sixth contact region 13b to each other.

The first connecting region 15a is separated from the second connecting region 16a only by a comparatively thin insulating foil. The third connecting region 15b is separated from the fourth connecting region 16b only by a comparatively thin insulating foil.

The first contact region 11a, the second contact region 12, the third contact region 13a, the fourth contact region 14, the fifth contact region 11b and the sixth contact region 13b are planar and arranged plane-parallel to the semiconductor module 20 or the intermediate circuit capacitor 30. The first connecting region 15a, the second connecting region 16a, the third connecting region 16b and the fourth connecting region 15b are arranged perpendicular to the semiconductor module 20 or the intermediate circuit capacitor 30.

The intermediate circuit capacitor 30 is designed with an intermediate circuit busbar. The first intermediate circuit contact region 31a and the third intermediate circuit contact region 31b are formed by an upper contact plate 34. The second intermediate circuit contact region 32 is formed by a lower contact plate 33 which is arranged below the upper contact plate 34. A window 35, which provides free access to the lower contact plate 33, is formed in the upper contact plate 34.

Since the fourth contact region 14 is electrically connected to the lower contact plate 33, but the lower contact plate 33 is arranged below the upper contact plate 34, the fourth contact region 14 is angled at two positions, causing the fourth contact region 14 to contact the second connecting region 16a and the third connecting region 16b at the level of the third contact region 13 and the sixth contact region 13b.

The first connecting region 15a is designed congruent with the second connecting region 16a. The third connecting region 16b is designed congruent with the fourth connecting region 15b.

Due to the design described, the positive and negative current paths through the individual connecting regions 15a, 15b, 16a, 16b between the semiconductor module 20 and the intermediate circuit capacitor 30 are approximately the same length.

This allows the opposite-polarity current-induced magnetic fields of the connecting device 10 to compensate each other particularly well.

In order to further reduce the intermediate circuit inductance, a plurality of semiconductor modules 20 or intermediate circuit capacitors 30 connected in parallel are connected by a plurality of connecting devices 10 which each share an adjacent contact region, in this case the fifth contact region 11b and the sixth contact region 13b.

For example, this measure allows an inductance of 1.24 nH to be achieved, which represents a reduction compared to a value of 2.72 nH for a standard ribbon bond solution.

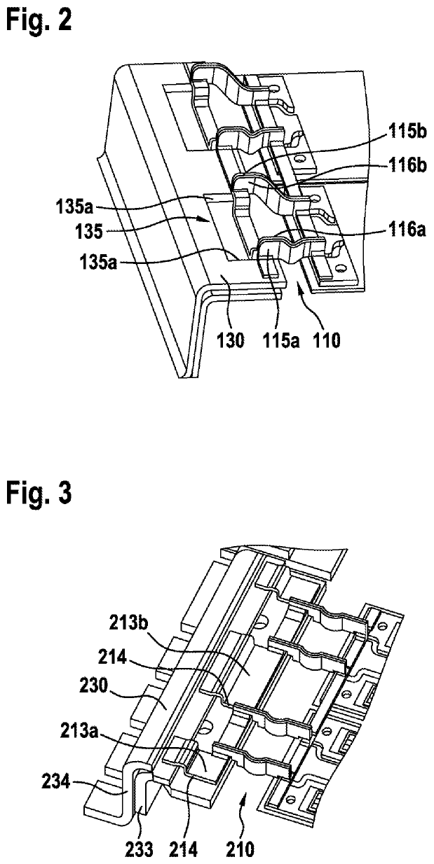

FIG. 2 shows a connecting device 110 according to a second embodiment. Essentially, the structure is identical to the connecting device 10 according to the first embodiment. In contrast, the connecting regions 115a, 115b, 116a, 116b are arranged on the intermediate circuit capacitor 130 and the window 135 is designed in such a way that the connecting regions 115a, 115b, 116a, 116b are each as close as possible to the respective edges 135a of the window 135.

For example, this allows the inductance to be lowered to 1.16 nH.

FIG. 3 shows a connecting device 210 according to a third embodiment. Essentially, the structure is identical to the connecting device 10 according to the first embodiment. In contrast to this, the intermediate circuit capacitor 230 is designed with a stepped intermediate circuit busbar. The upper contact plate 234 is designed as the upper step 234 and the lower contact plate 233 is designed as the lower step 233.

The upper contact plate 234 carries the positive potential. Therefore, the third contact region 213a and the sixth contact region 213b are also designed as steps which are guided over the lower step 233 to the upper step 234 in a planar manner, insulated from the lower step. The positive current path up to the upper step 234 is therefore longer than the negative current path to the lower step 233. This has a negative effect on the connection inductance.

Therefore, the fourth contact region 214 is extended in such a way that it is guided over the upper step 234 in an insulated manner. The fourth contact region 214 extends congruently below the third contact region 213a and the sixth contact region 213b. In this way, the positive current path and the negative current path are the same length, because the current chooses the path with the lowest inductance, which in this case leads through the extended second negative contact region 214.

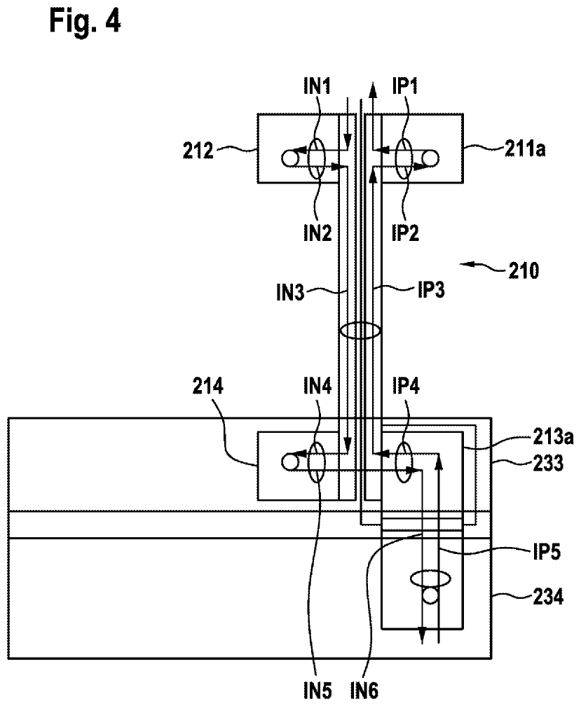

FIG. 4 shows the negative current path N and the positive current path P for the connecting device 210 according to the third embodiment.

The first positive current region IP1 and the second positive current region IP2 flow through the first contact region 211a. The first negative current region IN1 and the second negative current region IN2 flow through the second contact region 212. The third positive current region IP3 flows through the first connecting region 215a and the third negative current region IN3 flows through the second connecting region 216a. The fourth positive current region IP4 and the fifth positive current region IP5 flow through the third contact region 213a. The fourth negative current region IN4, the fifth negative current region IN5 and the sixth negative current region IN6 flow through the fourth contact region 214.

The magnetic field of the first negative current region IN1 and of the second negative current region IN2 compensate each other (represented by the circles on the current lines). The magnetic field of the first positive current region IP1 and the second positive current region IP2 compensate each other. The magnetic field of the third negative current region IN3 and the magnetic field of the third positive current region IP3 compensate each other. The magnetic field of the fourth negative current region IN4, of the fifth negative current region IN5 and of the fourth positive current region IP4 compensate each other. The magnetic field of the sixth negative current region IN6 and of the fifth positive current region IP5 compensate each other.

Since the current follows the path of the lowest inductance, the negative path does not end after the fourth negative current region IN4, but runs along the fifth current region IN5 and the sixth negative current region IN6.

In this way, the connection inductance can be reduced by 20% compared to a ribbon bond solution.

1. A low-inductance connecting device (10) for connecting a semiconductor module (20) to an intermediate circuit capacitor (30); the connecting device (10) comprising:
at least one first contact region (11a) and one second contact region (12) which has opposite polarity to the first contact region (11a), wherein the first and second contact regions are configured to contact the semiconductor module (20);
at least one third contact region (13a) which has the same polarity as the first contact region (11a) and one fourth contact region (14) which has opposite polarity to the third contact region (13a), wherein the third and fourth contact regions are configured to contact the intermediate circuit capacitor (30);
at least one first connecting region (15a) which is configured to connect the first contact region (11a) and the third contact region (13a) to one another; and
at least one second connecting region (16a) which is configured to connect the second contact region (12) and the fourth contact region (14) to one another; wherein
the first connecting region (15a) and the second connecting region (16a) are each configured as planar busbars which are separate from one another.

2. The connecting device as claimed in claim 1, wherein the first connecting region (15a) and the second connecting region (16a) are arranged plane-parallel to each other.

3. The connecting device as claimed in claim 1, wherein the first contact region (11a), the second contact region (12), the third contact region (13a) and the fourth contact region (14) are arranged plane-parallel to each other; wherein the first connecting region (15a) and the second connecting region (16a) are arranged perpendicular to the contact regions (11a, 12, 13a, 14).

4. The connecting device as claimed in claim 1, wherein the first connecting region (15a) and the second connecting region (16a) are separated from each other only by an insulating layer.

5. The connecting device as claimed in claim 1, wherein the first connecting region (15a) and the second connecting region (16a) are each configured as laminated planar busbars which are separate from one another.

6. The connecting device as claimed in claim 1, wherein a distance between the first connecting region (15a) and the second connecting region (16a) is constant.

7. The connecting device as claimed in claim 1, wherein the second connecting region (16a) is at least partially congruent with the first connecting region (15a).

8. The connecting device as claimed in claim 1, wherein the intermediate circuit capacitor (30) is configured with an intermediate circuit busbar.

9. The connecting device as claimed in claim 1, wherein the intermediate circuit capacitor (30) is configured with a stepped intermediate circuit busbar (230) with a first step (233) and a second step (234); wherein the second step (234) is offset parallel to the first step (233); wherein a contact region (214) which contacts the first step (233) is extended in such a way that the contact region (214) is guided over the second step (234) in a planar manner and insulated therefrom.

10. The connecting device as claimed in claim 1, wherein the second connecting region (16a) is at least partially congruent with the first connecting region (15a), and the second contact region (12) and/or the fourth contact region (14) are formed congruent with the respective first contact region (11a) and the third contact region (13a).
